(19) United States
(12) Patent Application Publication
(10) Pub. No.: US 2006/0063035 A1
(43) Pub. Date: Mar. 23, 2006

(54) Organic electroluminescence device, method for manufacturing organic electroluminescence device, and electronic apparatus

(75) Inventor: Katsuyuki Morii, Lausanne (CH)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 11/199,210

(22) Filed: Aug. 9, 2005

(30) Foreign Application Priority Data
Sep. 17, 2004 (JP) 2004-271508

(51) Int. Cl. H01L 51/50; H05B 33/12

(52) U.S. Cl. 428/690; 428/917; 313/504; 313/506; 427/66

(57) ABSTRACT

An organic electroluminescence device having a luminescence function portion in between electrodes, the luminescence function portion comprising: a first function portion composed of a high molecular compound having a luminescence function; a second function portion composed of a compound represented by the chemical formula (1); and an intermediate portion in which a high molecular compound having the luminescence function and a compound represented by the chemical formula (1) are mixed in between these first function portion and second function portion.

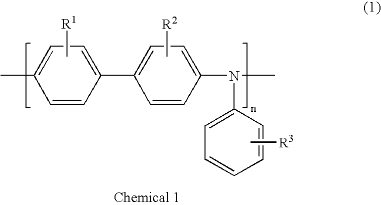

### BACKGROUND

The present invention relates to an organic electroluminescence device, a method for manufacturing the organic electroluminescence device, and an electronic apparatus.

In recent years, the development of organic electroluminescence (hereinafter, abbreviated to “organic EL”) devices using organic materials for spontaneous light emitting-type displays in place of liquid crystal displays has been accelerated. As the method for preparing such organic EL devices, a method for forming low molecular materials using a gaseous phase method such as an evaporation method, and a method for forming high molecular materials by means of a liquid phase method have been proposed. Appl. Phys. Lett. 51(12), 21 Sep. 1987, p. 913/Appl. Phys. Lett. 71(1), 7 Jul. 1997, p. 34 are the examples of the related art. Moreover, in order to improve the luminescence efficiency and durability in the organic EL devices, a hole injection/transportation layer (hereinafter, referred to as a “hole transportation layer”) is often formed in between an anode and a luminescence layer. As for the method for forming such a hole transportation layer or a buffer layer, in cases where a low molecular system material is used, a method for forming a phenyl amine derivative by evaporation method has been proposed, and moreover, in cases where a high molecular system material is used, a method for forming a film using a method, such as a spin coating method, of applying electrically conductive polymers, such as a poly thiophene derivative and a poly aniline derivative has been proposed. Nature 357, 477, 1992 is the example of the related art.

Incidentally, there are several problems in the organic EL devices described in the background art. The organic EL device is constituted by a multi-layered structure, and as to this multi-layered structure, a structure in which a hole transportation layer, a luminescence layer, and an electron transportation layer are sequentially deposited is common, and further in each layer the thickness, the thickness ratio, and the multi-layered structure are determined depending on the carrier mobility. For example, with respect to the hole transportation layer, the thickness of each layer is determined by the carrier mobility of holes, and with respect to the luminescence layer and the electron transport layer, it is determined by the carrier mobility of electrons, so that the holes and electrons are moved into the luminescence layer in a well-balanced manner. However, in such a structure the carrier mobility is balanced by depositing these layers, and therefore, for example, if the thickness of a hole transportation material becomes thicker, there are problems in that the luminescence will not occur in the luminescence layer unless the voltage is set higher so as to transport more holes, and in that the luminescence places become non-uniform, and the like.

Moreover, the luminescence characteristic of organic EL devices have the characteristic that a variation de of the luminescence efficiency (Efficiency) of the vertical axis varies sharply with respect to a variation dv of the driving voltage (V-drive) of the horizontal axis, as shown in FIG. 12. Specifically, it has the characteristic that the luminescence efficiency increases significantly just by increasing the driving voltage a little, and the luminescence efficiency decreases significantly just by decreasing the driving voltage a little. Such characteristic is thought to be due to the fact that the material of the various luminescence function layers concerned is in a uniform surface-contacting state in the interface of various luminescence function layers, such as the hole transportation layer and the luminescence layer, and therefore with an application of a predetermined amount of driving voltage, holes and electrons are exited simultaneously to combine, thereby emitting light. Accordingly, there is a problem that controlling of the luminescence intensity and luminescence efficiency of the organic EL device is difficult. In order to emit light with the intensity of a desired gray scale, a driver circuit capable of finely controlling the variation dv of the driving voltage is needed, and there is a problem that the periphery circuit becomes complicated. From a viewpoint of life of the element, this means that only the limited molecules are excited repeatedly, which can be said a demerit.

### SUMMARY

An advantage of the invention is to provide an organic electroluminescence device with which a higher efficiency and a longer life of the luminescence characteristic is achieved, and the gray-scale control is made easier, a method for manufacturing the same, and an electronic apparatus provided with this organic electroluminescence device.

According to a first aspect of the invention, the organic electroluminescence device (the organic EL device) is an organic EL device having a luminescence function portion in between electrodes, wherein the luminescence function portion includes: a first function portion composed of a high molecular compound having a luminescence function; a second function portion composed of a compound represented by the chemical formula (1) shown in Chemical 1; and an intermediate portion in which a high molecular compound having the luminescence function and a compound represented by the chemical formula (1) are mixed between these first function portion and second function portion.

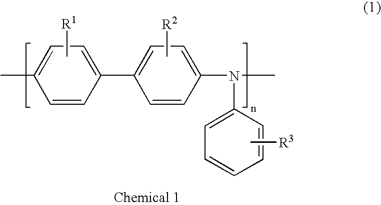

By constituting the luminescence function portion by the multi-layered structure made of the high molecular material including an interlayer, specifically including a phase separation interface in this manner, an advantageous effect is obtained as compared with the case where the multi-layered structure of a low molecular material is formed.

Specifically, since the low molecular material is generally formed in an amorphous shape, the molecules are disposed isotropically in each layer, and as a result, the carrier mobility is also made isotropic in each layer. Then, the thickness of each layer constituting the multi-layered structure is determined so that the carrier mobility may be balanced favorably. Here, although the evaporation method is generally used in order to deposit and form the low molecular material, the interface of the multi-layered films formed with this evaporation method is in a uniform face-contacting state without the material of each layer being mixed. Accordingly, in such a multi-layered structure the carrier mobility is balanced by the multi-layered layers, therefore, for example, if the thickness of hole-transportation material is made thick, the luminescence will not occur in the luminescence layer, or the luminescence places become non-uniform, and the like unless the voltage is set higher so as to transport more holes. Then, since the interface of the respective layers is a uniform junction face, holes and electrons are excited simultaneously to combine, thereby emitting light with a little increase of the amount of driving voltage.

On the other hand, in the luminescence function layer composed of high molecular materials according to the invention, an intermediate portion is formed in between the first function portion and the second function portion, and the interface (in the face-contacting state) like the one in the case where the low molecular material is used is not formed. Therefore, it is possible to improve the luminescence efficiency, consequently improving life of the luminescence. Then, since holes and electrons are not be excited to combine simultaneously even if the amount of driving voltage is increased, the luminescence intensity will not increase sharply, the intensity can be gradually increased according to the amount of driving voltages, and controlling of the luminescence efficiency of organic EL devices and the gray-scale control at low intensity can be carried out easily. Moreover, there is an advantage that the complicated periphery circuit for finely controlling the variation of the driving voltage is not needed.

It is preferable that the intermediate portion be a region in which the high molecular compound having the luminescence function, and the compound represented by the chemical formula (1) are distributed non-uniformly in the thickness direction of the luminescence function portion or be a region where the respective compounds are mixed. It is also preferable that, in the organic EL device of the invention, the high molecular compound having the luminescence function configure the luminescence portion serving as a luminescence body, and the compound represented by the chemical formula (1) configure a hole-transportation portion for transporting holes to the luminescence portion from the electrode.

It is also preferable that the molecular weight of the compound represented by the chemical formula (1) be 50,000 or less, and more preferably less than 20,000. This is because, if the molecular weight exceeds 50,000, the treatment in the manufacturing (solubility to the solvent or the like) will degrade, and therefore, the luminescence efficiency may decrease and the luminescence life may also decrease. This is considered to be due to the fact that if the molecular weight increases, the compatibility of the compound represented by the chemical formula (1) and the high molecular compound having the luminescence function in the intermediate portion will decrease and thus a relatively stable interface is formed in the intermediate portion.

It is also preferable that the thickness of the luminescence function portion be set in the range from 100 nm to 140 nm. This is because if it is less than 100 nm or more than 140 nm, there are cases where the luminescence efficiency may decrease. One of the causes thereof is thought to be due to the fact that the structure of the intermediate portion varies in accordance with the thickness of the luminescence function portion to thereby obtain a suitable phase structure in the above-described range of the thickness. This result is very characteristic in the organic EL in which the film thickness is severe, and it is a big advantage in the manufacturing.

A second aspect of the invention is a method for manufacturing an organic EL device having a luminescence function portion in between electrodes, the method includes: forming an electrode on a substrate; applying onto the electrode a mixed solution in which a high molecular compound having a luminescence function and a compound represented by the chemical formula (1) shown in Chemical 1 are mixed; and drying the applied solution.

The organic EL device of the invention is obtained readily just by applying the solution in which the both compounds are mixed, and drying this, as described above. Specifically, for example, an indium tin oxide (ITO) as the electrode is formed on the substrate using a gaseous phase method, and then, after patterning this, the above-described mixed solution is applied to the substrate including this electrode using the spin coating method, and is dried, so that the above-described luminescence function portion can be obtained. In addition, xylene can be used as the solvent for the mixed solution.

The above mixed solution may be prepared with a mixing ratio of the high molecular compound having the luminescence function and the compound represented by the chemical formula (1) in the range from 1:2 to 1:5. If there are few high molecular compounds having the luminescence function, the hole-transportation portion becomes excessive as compared with the luminescence portion, and thus the holes will be transported to the luminescence portion excessively, such that the luminescence efficiency may decrease. On the other hand, if there are few compounds represented by the chemical formula (1), the luminescence portion becomes excessive as compared with the hole-transportation portion, and thus the holes may be transported to the luminescence portion sufficiently, thereby decreasing the luminescence efficiency. This result, as well as the film thickness, is also considered to be a big advantage in the manufacturing.

According to a third aspect of the invention, an electronic apparatus is provided with the organic EL device described above. Accordingly, it is possible to provide the electronic apparatus enabling a long-life and bright display.

### BRIEF DESCRIPTION OF THE DRAWINGS

The invention will be described with reference to the accompanying drawings, wherein like numbers reference like elements, and wherein:

FIG. 1 is a sectional view showing an organic EL device of an embodiment of the invention;

FIG. 2 is a sectional view for explaining a manufacturing process of the organic EL device of FIG. 1;

FIG. 3 is a sectional view for explaining the manufacturing process of the organic EL device of FIG. 1;

FIG. 4 is a sectional view for explaining the manufacturing process of the organic EL device of FIG. 1;

FIG. 5 is a sectional view for explaining the manufacturing process of the organic EL device of FIG. 1;

FIG. 6 is a view for explaining the detailed configuration of a luminescence function portion;

FIG. 7 is a view for explaining the luminescence characteristic of the organic EL device of the invention;

FIGS. 8(a) to (c) are perspective views showing an electronic apparatus provided with the organic EL device of the invention;

FIG. 9 is a view showing a relationship between the molecular weight of compound used for a hole injection/transportation material, and the luminescence efficiency;

FIG. 10 is a view showing a relationship between the thickness of a luminescence function portion and the luminescence efficiency;

FIG. 11 is a view showing a relationship between the mixing ratio of the hole injection/transportation material and a luminescent material, and the luminescence efficiency; and

FIG. 12 is a view for explaining the luminescence characteristic of the conventional organic EL device.

### DETAILED DESCRIPTION OF EMBODIMENTS

Hereinafter, embodiments of the invention will be described with reference to the accompanying drawings. In addition, in each view, the scale of each layer or each element is differentiated from each other in order that each layer or each element has a size capable of being identified in the view.

(Organic EL Device)

First, an organic EL device corresponding to an embodiment of the invention will be described.

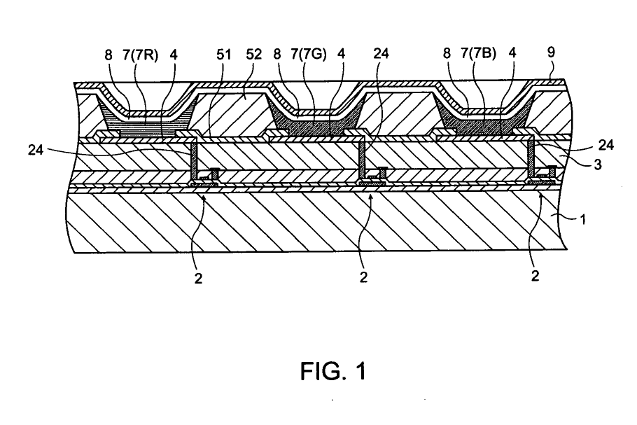

The organic EL device of the embodiment is a color light emitting-type organic EL device, and has a cross-sectional structure as shown in FIG. 1. Specifically, it consists of a structure in which a thin film transistor (TFT) 2 as a circuit element, an interlayer insulating film (an insulating layer) 3, a pixel electrode (an anode) 4, a luminescence function portion 7, cathode 8 and 9, and the like are deposited sequentially on a translucent substrates 1, such as glass.

As to the substrate 1, a glass substrate is used in this embodiment. Other than the glass substrate, various known substrates used for electro optic apparatus and circuit boards, such as a silicon substrate, a quartz substrate, a ceramic substrate, a metal substrate, a plastic substrate, and a plastics film substrate are applied. In the face of the substrate 1, a plurality of pixel regions as the luminescence region are arranged in a matrix shape, and when carrying out color displaying, the pixel regions corresponding to each color of, for example, red (R), green (G), and blue (B) are configured in a predetermined arrangement. The pixel electrode 4 is arranged in each pixel region, and signal lines, power supply lines, scanning lines, or the like, which are not shown, are arranged in the vicinity thereof.

Moreover, TFT 2 formed in the substrate 1 is provided in each pixel region on one by one basis, and is electrically coupled to the pixel electrode (the anode) 4 through the interlayer insulating film 3. The pixel electrode (the anode) 4 is arranged in a matrix shape, and faces to the cathodes 8 and 9 with a luminescence function portion 7 being interposed therebetween. Each luminescence function portion 7 includes a red luminescence function portion 7R for emitting red (R) light, a green luminescence function portion 7G for emitting green (G) light, and a blue luminescence function portion 7B for emitting blue (B) light, and is separated by bank portions (partitioning portions) 51 and 52 in between respective color luminescence function portions.

Among the bank portions 51 and 52, the first bank portion 51 is formed of an inorganic material such as SiO₂ or the like, while the second bank portion 52 is formed of an organic material, such as an acrylate resin. Moreover, the first bank portion 51 is arranged on top of the interlayer insulating film 3 so as to cover a part of the outer edge of the pixel electrode 4, and is configured including an opening in order to arrange the luminescence function portion 7 therein. Furthermore, the second bank portion 52 has an opening with the diameter larger than the opening of the first bank portion 51 on top of the first bank portion 51, so that the luminescence function portion 7 is arranged in this opening.

Next, the cathodes (the counter electrodes) 8 and 9 are formed, across each pixel region, in the entire face of the substrate 1, and have a role, paired with the pixel electrode 4, to flow an electric current to the luminescence function portion 7, and are configured with a calcium layer 8 and an aluminum layer 9 being deposited.

In the organic EL device of the embodiment, the light emitted from the luminescence function portion 7 to the substrate 1 side transmits through the interlayer insulating film 3 and the substrate 1, and is emitted to the lower side of the substrate 1 (the light outgoing side), while the light emitted from the luminescence function portion 7 to the opposite side of the substrate 1 is reflected by the cathode 9 made of aluminum, thereby transmitting through the interlayer insulating film 3 and the substrate 1, and is emitted to the lower side of the substrate 1.

Here, the luminescence function portion 7 has a phase structure as shown in FIG. 6(a), and specifically, includes: a first function portion 7b composed of a high molecular compound having the luminescence function; a second function portion 7a composed of a compound represented by the chemical formula (1) shown in Chemical 2; and an intermediate portion 7c in which a high molecular compound having the luminescence function and a compound represented by the chemical formula (1) shown in Chemical 2 are mixed in between these first function portion 7b and second function portion 7a. In addition, here, the second function portion 7a constitutes the luminescence portion, and the first function portion 7a constitutes the hole injection/transportation portion.

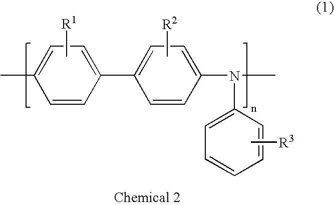

Moreover, as to the compound constituting the first function portion 7b, high molecular compounds as shown in Chemical 3 through Chemical 9 can be exemplified.

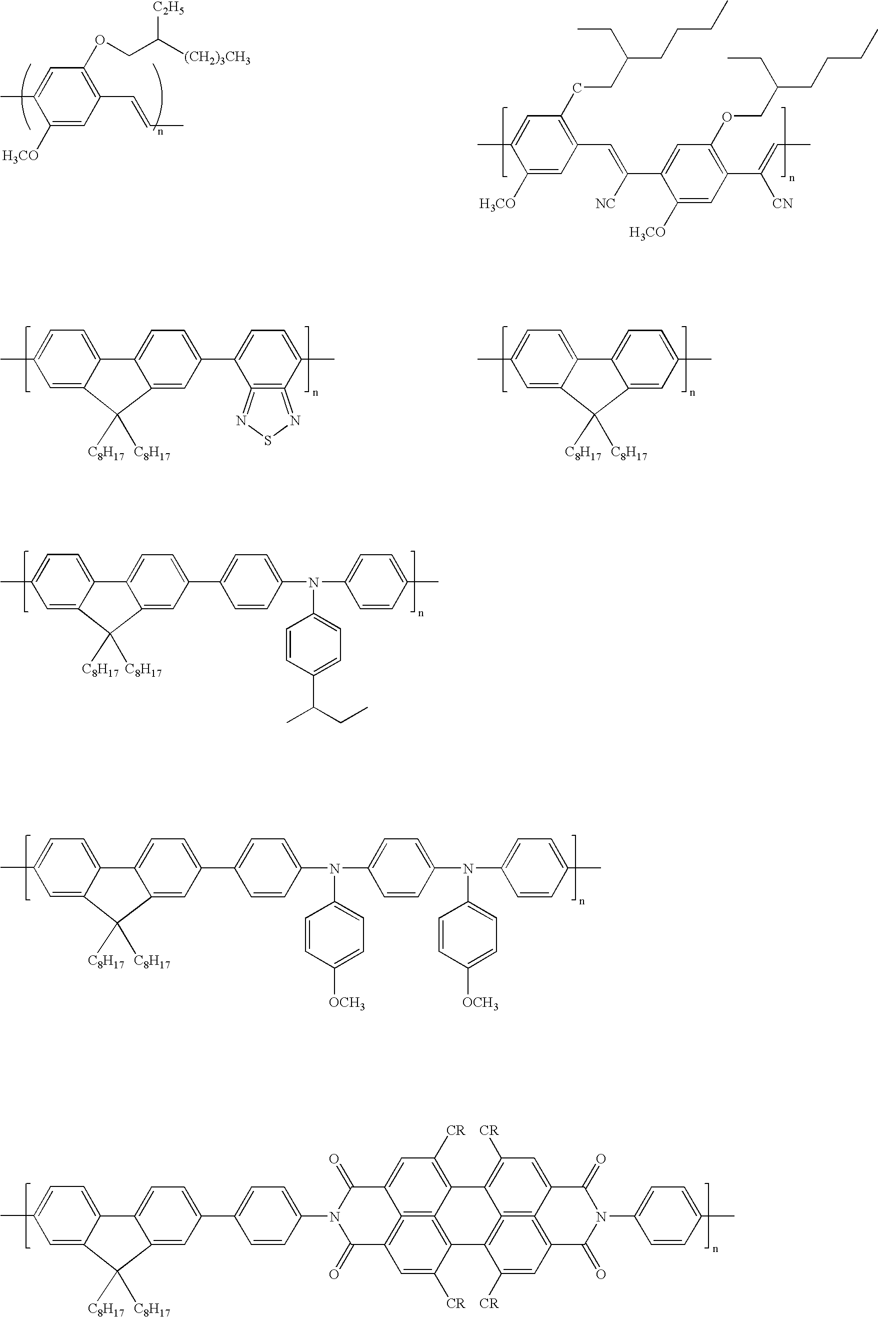

In the specific configuration of the intermediate portion 7c, as shown in FIG. 6(b), a high molecular compound having the luminescence function and a compound represented by the chemical formula (1) are mixed in the thickness direction, and the both compounds are distributed non-uniformly in the thickness direction of the luminescence function portion 7. That is, in the luminescence function portion 7, an interface parallel to the electrode is not formed in between the first function portion 7b and the second function portion 7a, and the both compounds are mixed in the intermediate portion 7c.

In this manner, the luminescence function portion 7 is constituted by a multi-layered structure composed of the first function portion (the luminescence portion) 7b, the second function portion (the hole-injection/transportation portion) 7a, and the intermediate portion 7c made of a high molecular material, so that an interface (in the face-contacting state) like in the related art is not formed in between the luminescence portion and the hole injection/transportation portion. Thereby, it is possible to improve the luminescence efficiency, consequently improving the luminescence life. Then, since holes and electrons will not be excited to combine simultaneously even if the amount of driving voltage for the luminescence function portion 7 is increased, the luminescence intensity will not increase sharply, the intensity can be gradually increased in response to the amount of driving voltages, and controlling of the luminescence efficiency of the organic EL device and the gray-scale control at low intensity can be carried out easily.

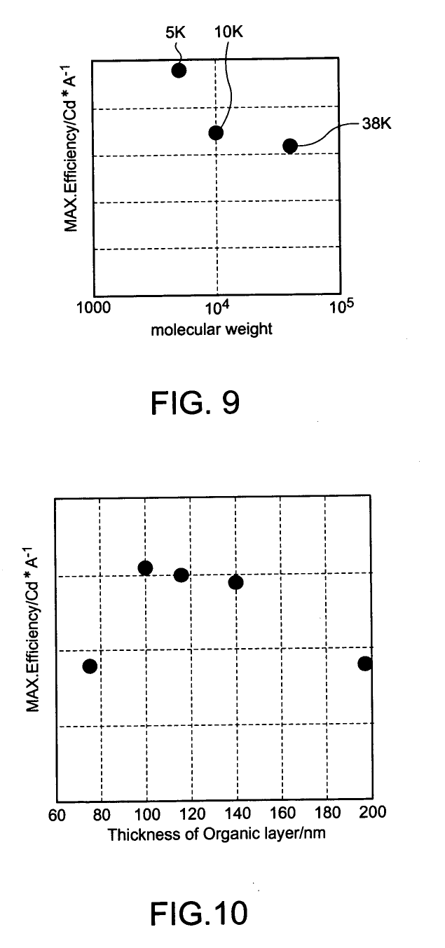

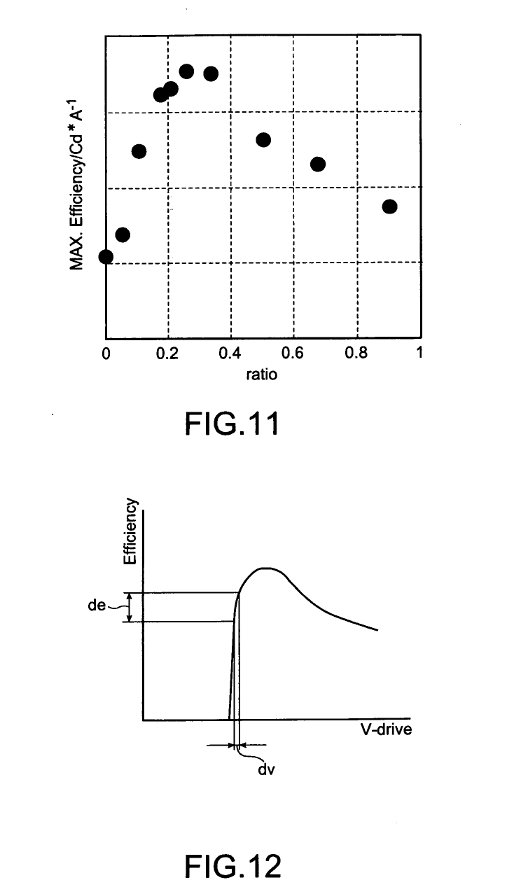

In addition, the molecular weight of the compound represented by the chemical formula (1) used in the organic EL device of the embodiment is 50,000 or less, and preferably less than 20,000. If the molecular weight exceeds 50,000 (50k), the treatment in the manufacturing (solubility in the solvent or the like) will degrade, and in addition, as shown in FIG. 9, the luminescence efficiency may decrease, and the luminescence life may also decrease. This is thought to be due to the fact that if the molecular weight increases, the compatibility between the compound represented by the chemical formula (1) and the high molecular compound having the luminescence function will decrease in the intermediate portion 7c, thereby forming a relatively stable interface in the intermediate portion 7c.

Moreover, the thickness of the luminescence function portion 7 is set to in the range from 100 nm to 140 nm in the organic EL device of the embodiment. This is because if the thickness of the luminescence function portion 7 becomes less than 100 nm or exceeds 140 nm, the luminescence efficiency may decrease as shown in FIG. 10. Although the cause thereof is not certain, it is thought to be due to the fact that the structure of the intermediate portion 7c varies in accordance with the thickness of the luminescence function portion 7, and a suitable phase structure is obtained in the above-described range of the thicknesses.

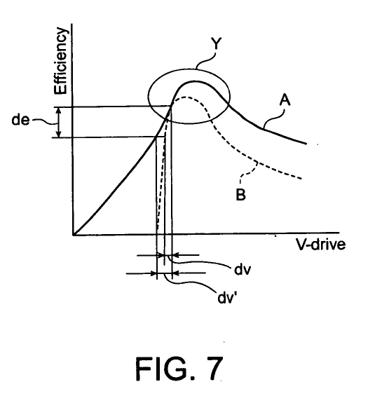

Here, the luminescence characteristic of the organic EL device of the embodiment will be described with reference to FIG. 7. FIG. 7 is a view showing the experimental results of luminescence characteristic of the organic EL device, showing the driving voltage (V-drive) in the horizontal axis, and the luminescence efficiency (Efficiency) in the vertical axis, respectively. In this view, the curve referred to as a numeral A indicates the luminescence characteristic of the organic EL device (the embodiment) of the embodiment, and the curve referred to as a numeral B indicates the luminescence characteristic of the organic EL device (the conventional example) without having the intermediate portion 7c.

As shown in FIG. 7, in the conventional example, there is shown characteristic that the variation de of the luminescence efficiency varies sharply with respect to the variation dv of the driving voltage. Specifically, it has the characteristic that the luminescence efficiency and luminescence intensity will increase significantly just by increasing the driving voltage a little, and the luminescence efficiency and luminescence intensity will decrease significantly just by decreasing the driving voltage a little. On the other hand, the embodiment has a more gradual curve than the characteristic curve of the conventional example, and it is apparent that the variation de of the luminescence efficiency is obtained with the variation dv′ whose voltage width is larger than the above-described variation dv. Accordingly, in the embodiment, it is apparent that the luminescence efficiency can be varied without supplying the driving voltage with high precision and high resolution, and thus the gray-scale control at low intensity can be carried out easily. Furthermore, the result that the maximum luminescence efficiency of the embodiment is higher than the conventional example (refer to the Y portion in the view) is obtained. Furthermore, at higher voltages, the degree of decrease of the luminescence efficiency is small in the embodiment, resulting in indication of spreading of the luminescence location.

(Method for Manufacturing an Organic EL Device)

Next, a method for manufacturing an organic EL device will be described.

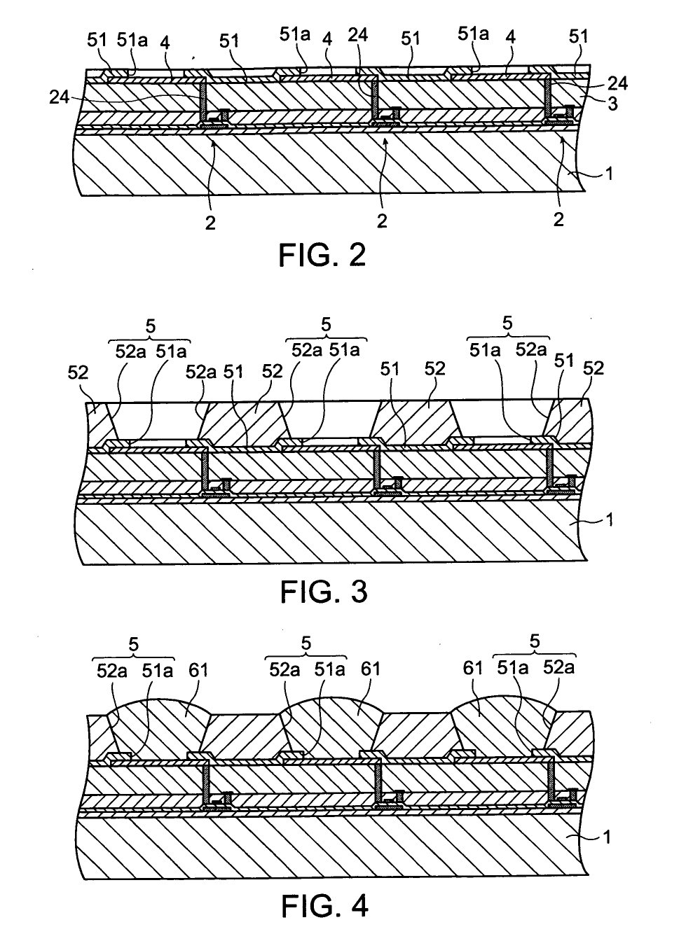

First, as shown in FIG. 2, after forming a thin film transistor 2 for each pixel on a glass substrate 1, an insulating layer 3 is formed. Next, in this insulating layer 3, a contact 24 for coupling each thin film transistor 2 to the pixel electrode 4 is formed. Then, the pixel electrode 4 composed of ITO (In₂O₃—SnO₂) is formed corresponding to each pixel. Specifically, the manufacturing is carried out through the ITO thin film formation process, a photolithography process, and an etching process.

Next, the first bank portion (a partitioning wall) 51 made of silicon oxide having an opening 51a, the opening 51a corresponding to each luminescence region, is formed on this glass substrate 1 through a silicon-oxide thin film formation process, a photolithography process, and an etching process. In addition, the first bank portion 51 is formed so that the peripheral portion of the opening 51a may overlap with the outer edge of the anode 4.

Next, as shown in FIG. 3, the second bank portion (a partitioning wall) 52 having an opening 52a, the opening 52a corresponding to each luminescence region, is formed on the first bank portion 51. This second bank portion 52 is made of a poly acrylate resin, and is formed through an application process of a solution containing the poly acrylate resin, a drying process of the applied film, a photolithography process, and an etching process.

The opening 52a of the second bank portion 52 is formed in a tapered shape, wherein the cross section intersecting with the substrate face at right angle becomes smaller on the glass substrate 1 side, and becomes larger towards the side being away from the glass substrate 1. Moreover, the area of the opening 52a of the second bank portion 52 is larger than that of the opening 51a of the first bank portion 51 even at the location closest to the glass substrate 1 side. Accordingly, the partitioning wall having an opening 5 with a two-level structure is formed. In addition, the luminescence region for each pixel is precisely controlled by the opening 51a of the first bank portion 51. Moreover, the second bank portion 52 is formed in a predetermined thickness in order to secure the depth of the opening 5, and it is formed in a tapered shape so that a dropped solution is facilitated to enter into the opening 5 even if the dropped solution is put on the upper face of the bank portion 52.

Next, as shown in FIG. 4, a luminescence function portion formation material 61 is applied and formed inside each opening 5.

Here, as the method for applying the luminescence-portion formation material 61, a well-known liquid phase method (a wet process, a wet-application method) is adopted, and for example, a spin coating method, an ink-jet (a droplet discharging) method, a slit coating method, a dip coating method, a spray film-forming method, a printing method, or the like are used. Such a liquid phase method is a suitable method for film-forming a high molecular material, and thus the organic EL device can be manufactured without using the expensive equipment such as vacuum equipment, at a lower price as compared with the gaseous phase method.

In the embodiment, it is preferable to use the spin coating method (for example, 2,000 rpm/30 sec). By using the liquid phase method in this manner, the luminescence function portion formation material 61 is formed on each pixel electrode 4 in each opening 5.

The luminescence function portion formation material is a material for forming the portion corresponding to the above-described luminescence function portion 7 of the organic EL device, in which further the hole injection/transportation material for forming the hole injection/transportation layer (the function layer), and the luminescent material for forming the luminescence layer (the function layer) are mixed and dissolved in the solvent. It is preferable to adopt, as the hole injection/transportation material, the high molecular compound represented by the chemical formula (1) of the above-described Chemical 2. Moreover, likewise, it is preferable to adopt, as the luminescent material, the high molecular compound of the chemical formulas represented by the above Chemical 3 through Chemical 9. In addition, the high molecular compound having the luminescence function is not restricted to the above ones, and other ones can be employed as long as the application is possible. Furthermore, it is preferable to adopt xylene as the solvent to dissolve these. In addition, solvents other than xylene may be adopted, and for example, cyclohexylbenzene, dihydrobenzofuran, trimethylbenzene, tetramethyllbenzene, or the like can be used.

More specifically, it can be exemplified that, for example, by mixing a high molecular compound represented by the chemical formula (1) (for example, in the chemical formula (1), R1 and R2 represent a hydrogen atom, and R3 represents a compound with about 10,000 molecular weight of a straight chain butyl radical) and a high molecular compound having the luminescence function in the weight ratio of 1:2, and dissolving this in xylene, 3% by weight of a xylene solution can be obtained. The high molecular compound represented by the chemical formula (1) can be synthesized using the method described in Japanese Unexamined Patent Publication No. H-11-21349. Moreover, it is preferable, in particular, to use a high molecular compound in which the polymer end is protected with phenylbromide and/or diphenylamine as required. With respect to the obtained high molecular compound, it is further preferable to remove trace metal components (for example, Na, Pd, or the like) to refine for use, suitably using a reprecipitation method, a column chromatography method, or the like.

In the chemical formula (1), the substituents R1, R2, and R3 are not restricted in particular as long as they meet the above-described definition, however, specifically, they include: a hydrogen atom; a methyl radical; an ethyl radical; an n-propyl radical; an isopropyl radical; an n-butyl radical; an isobutyl radical; a sec-butyl radical; a tert-butyl radical; an n-pentyl radical; an isopentyl radical; an neopentyl radical; a tert-pentyl radical; a cyclopentyl radical; an n-hexyl radical; 2-ethyl butyl-radical; a 3,3-dimethylbutyl radical; a cyclohexyl radical; an n-heptyl radical; a cyclohexylmethyl radical; an n-octyl radical; a tert-octyl radical; a 2-ethyl hexyl radical; an n-nonyl radical; an alkyl radical of a straight-chain, a straight-chain and a branched chain or a cyclic chain with carbon numbers of 1-18, such as an n-decyl radical; a methoxy radical; an ethoxy radical; an n-propoxy radical; an isopropoxy radical; an n-butoxy radical; a sec-butoxy radical; an n-pentyloxy-radical; an isopentyloxy radical; an neopentyloxy-radical; a cyclopentyloxy radical; an n-hexyl oxy-radical; a 2-ethyl butoxy radical, a 3,3-dimethyl butoxy radical; a cyclo hexyloxy radical; an n-heptyl oxy-radical; a cyclohexylmethyloxy radical; an n-octyloxy radical; a 2-ethylhexyloxy radical; an n-nonyloxy radical; and an alkoxy radical of a straight-chain, a straight-chain and a branched chain or a cyclic chain with carbon numbers of 1-18, such an n-decyloxy radical. Among them, a preferable example of the chemical formula (1) is the one in which R1 and R2 are hydrogen atoms, and R3 is an alkyl radical of a straight chain, a straight chain, and a branch chain, or a cyclic chain with carbon numbers of 3-8.

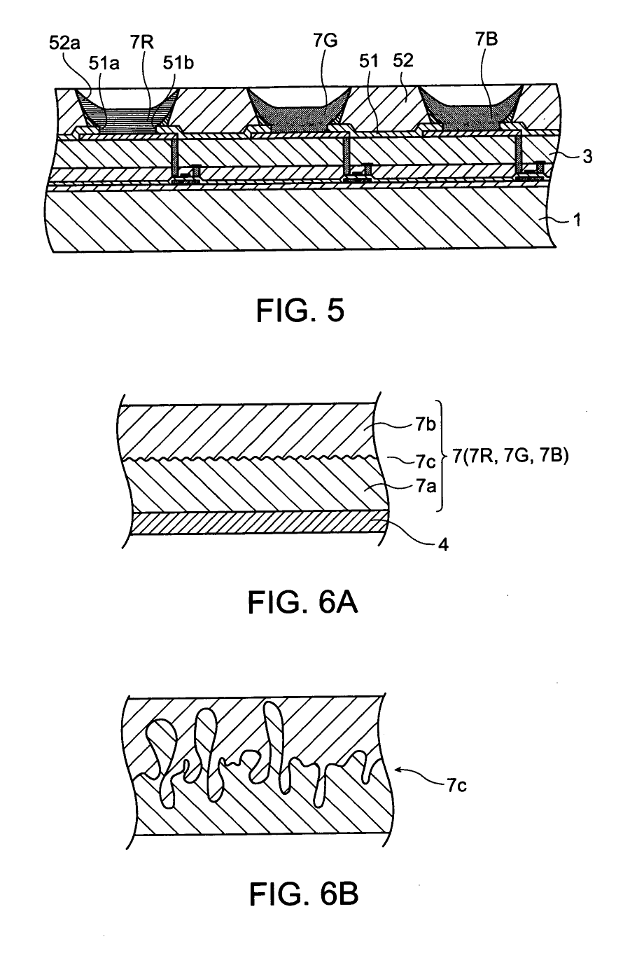

If drying is carried out after applying and forming the luminescence function portion formation materials described above, the luminescence function portions 7R, 7G, and 7B of each color will be formed on each pixel electrode 4 as shown in FIG. 5. Then, by forming a high molecular material like the ones of the embodiment with a liquid phase method (the spin coating method), a configuration in which the intermediate portion is formed in between the first function portion 7b and second function portion 7a as shown in FIG. 6 can be obtained.

Accordingly, as shown in FIG. 1, the second cathode (the electrode) 9 is formed over the entire surface on the substrate 1 (i.e., above the first cathode 8 in the opening 5 corresponding to the inside of the pixel region, and above the second partitioning wall 52).

In addition, the formation of respective cathodes 8 and 9 can also be formed with the conventionally well-known vacuum evaporation method.

Next, an epoxy resin system adhesive is applied, in a predetermined thickness, to the entire upper face of the substrate 1, and to the outer side face of the second partitioning wall 52 existing in the periphery position of the substrate face, and this adhesive will be cured in the state that the glass plate is being put thereon. Namely, the entire upper face of the second cathode 9 is covered with the epoxy resin system adhesive. The organic EL device is completed by carrying out sealing with a sealing agent and the glass plate in this manner.

Then, by attaching the organic EL device to the body having a drive circuit or the like, an organic EL display panel provided with the organic EL device is completed.

(Electronic Apparatus)

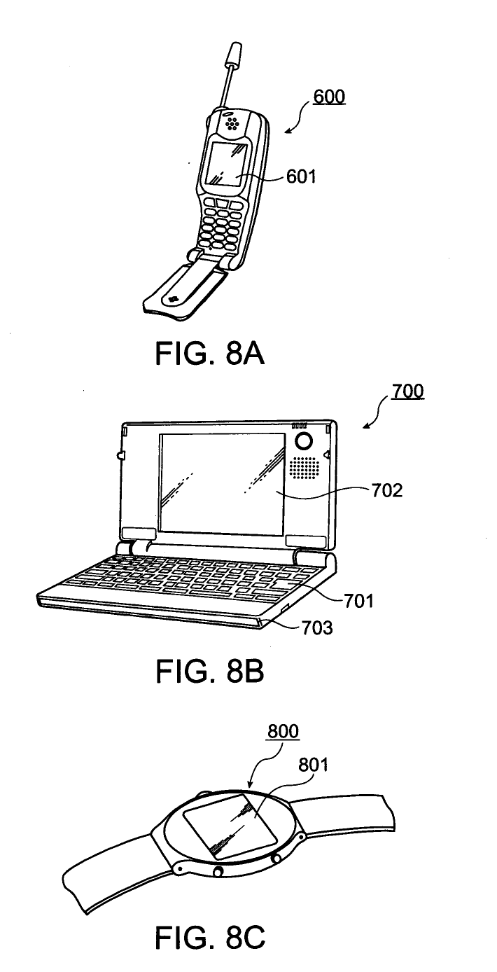

Next, various electronic apparatus provided with the organic EL device of the invention will be described with reference to FIG. 8. FIG. 8(a) is a perspective view showing an example of a cellular phone. In FIG. 8(a), a numeral 600 refers to the body of the cellular phone, and a numeral 601 refers to a display portion using the above-described organic EL device. FIG. 8(b) is a perspective view showing an example of portable type information processing devices, such as a word processor and a personal computer. In FIG. 8 (b), a numeral 700 refers to an information processing device, a numeral 701 refers to an input section, such as a keyboard, a numeral 703 refers to the body of an information processing device, and a numeral 702 refers to a display section using the above-described organic EL device. FIG. 8(c) is a perspective view showing an example of a wrist watch type electronic apparatus. In FIG. 8(c), a numeral 800 refers to the body of a clock, and a numeral 801 refers to a display section using the above-described organic EL device.

Since each of the electronic apparatus shown in FIGS. 8(a)-(c) is provided with the organic EL device of the embodiment as the display section, it is possible to realize displaying with an excellent luminescence efficiency and a long life.

What is claimed is:

1. An organic electroluminescence device having a luminescence function portion in between electrodes, the luminescence function portion comprising:
a first function portion composed of a high molecular compound having a luminescence function;
a second function portion composed of a compound represented by the chemical formula (1); and
an intermediate portion in which a high molecular compound having the luminescence function and a compound represented by the chemical formula (1) is mixed in between these first function portion and second function portion.

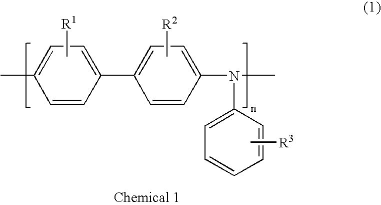

2. The organic electroluminescence device according to claim 1, wherein the intermediate portion is a region in which the high molecular compound having the luminescence function, and the compound represented by the chemical formula (1) are distributed non-uniformly in the thickness direction of the luminescence function portion.

3. The organic electroluminescence device according to claim 1, wherein the intermediate portion is a region in which the high molecular compound having the luminescence function and the compound represented by the chemical formula (1) are mixed in the thickness direction of the luminescence function portion.

4. The organic electroluminescence device according to claim 1, wherein the molecular weight of the compound represented by the chemical formula (1) is 50,000 or less.

5. The organic electroluminescence device according to claim 1, wherein the thickness of the luminescence function portion is set in the range from 100 nm to 140 nm.

6. The organic electroluminescence device according to claim 1, wherein the high molecular compound having the luminescence function configures a luminescence portion serving as a luminescence body, and the compound represented by the chemical formula (1) configures a hole-transportation portion for transporting holes to the luminescence portion from the electrode.

7. A method for manufacturing an organic electroluminescence device having a luminescence function portion in between electrodes, the method comprising:
forming an electrode on a substrate;
applying onto the electrode a mixed solution in which a high molecular compound having a luminescence function and a compound represented by the chemical formula (1) are mixed; and
drying the applied solution.

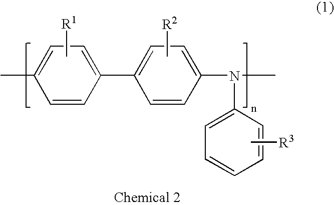

8. The method for manufacturing the organic electroluminescence device according to claim 7, wherein the mixed solution has a mixing ratio of the high molecular compound having the luminescence function and the compound represented by the chemical formula (1) in the range from 1:2 to 1:5.

9. An electronic apparatus, comprising the organic electroluminescence device according to claim 1.
